(19) United States
(12) Patent Application Publication
(10) Pub. No.: US 2026/0322060 A1
(43) Pub. Date: Oct. 15, 2026

(54) HIGH CONFINEMENT OPTICAL WAVEGUIDE AMPLIFIERS

(71) Applicant: HEWLETT PACKARD ENTERPRISE DEVELOPMENT LP, Spring, TX (US)

(72) Inventor: Sagi Varghese Mathai, Sunnyvale, CA (US)

(21) Appl. No.: 19/176,491

(22) Filed: Apr. 11, 2025

(51) Int. Cl. H01S 3/067

(52) U.S. Cl. CPC H01S 3/06729

(57) ABSTRACT

An optical device comprises a waveguide optical amplifier. The waveguide optical amplifier is formed on a substrate and comprises a core defining an optical path through the waveguide optical amplifier and cladding abutting at least one side of the core. The core comprises a first high-index strip comprising a first material with a first refractive index, a second high-index strip comprising a second material with a second refractive index, and a low-index strip sandwiched between the first and second high-index strips and comprising a third material with a third refractive index, which is lower than the first and second refractive indices. At least the third material is doped with a dopant, such as a rare earth element, configured to amplify signal light traveling through the optical path.

### INTRODUCTION

In photonic (light-based) communications, information is encoded in light signals and transmitted through photonic interconnects, such as optical fibers. As light is transmitted through such interconnects, the light signals tend to diminish in strength due to dispersion, leakage, or other effects. Thus, to avoid the signal becoming too weak, optical amplifiers are generally added periodically in a photonic network to amplify the light signals.

One type of optical amplifier is a fiber optical amplifier (FOA), which comprises a length of optical fiber which has been doped with certain elements. As a light signal is transmitted through this optical fiber, it interacts with the dopant atoms and is amplified via the phenomenon of stimulated emission. In particular, a process called “pumping” is used to excite the dopant, which comprises passing light having a particular wavelength (“pump light”) through the waveguide, with the pump light being absorbed by the dopant atoms and thereby causing electrons of the dopant atoms to be excited from a ground energy state to an excited energy state. Then the information-carrying light signal which is to be amplified is passed through the waveguide, and when this signal light encounters an excited dopant atom, the signal light will interact with the excited electron of the dopant atom and cause the electron to transition to a lower energy state and also release a photon (light). The released photon has the same wavelength and travels in the same direction as the original signal light, and thus the released photon joins with the signal light, increasing the overall intensity of the signal. Many such stimulated emissions occur as the signal light passes through the waveguide, resulting in the signal light that exits the waveguide having an intensity that is greatly amplified compared to the signal light that entered the waveguide.

Another type of optical amplifier is a semiconductor optical amplifier (SOA), which is formed using III-V semiconductor media. These SOA use quantum dots, quantum wells or bulk semiconductors, and the phenomenon of hole/electron recombination to amplify the light signal.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a schematic cross-section of an optical device comprising a waveguide optical amplifier (WOA), with the section taken along 1-1 in FIG. 2.

FIG. 2 is a schematic plan view of another optical device, which is an example of the optical device of FIG. 1.

FIG. 3 is a schematic cross-section of another optical device, which is an example of the optical device of FIG. 1.

FIG. 4 is graph of an optical mode profile of the WOA of the optical device of FIG. 3.

FIG. 5 is a schematic cross-section of another optical device, which is an example of the optical device of FIG. 1.

FIG. 6 is graph of an optical mode profile of the WOA of the optical device of FIG. 5.

FIG. 7 is a block diagram illustrating an optical circuit comprising an optical device and forward pumping components.

FIG. 8 is a block diagram illustrating another optical circuit comprising an optical device with forward and reverse pumping components.

FIG. 9 is a schematic cross-section of another optical device, which is an example of the optical device of FIG. 1.

FIG. 10 is a schematic cross-section of another optical device, which is an example of the optical device of FIG. 1.

FIG. 11 is a schematic cross-section of another example optical device, which includes a WOA which is a variation of the WOA of FIG. 1.

FIG. 12 is a schematic cross-section of another example optical device, which is an example of the optical device of FIG. 1.

### DETAILED DESCRIPTION

In some contexts, it may be desirable to have an optical amplifier which is small, capable of being integrated into the same integrated photonic circuit as other optical components, easy and inexpensive to manufacture, and capable of providing good amplification performance (e.g., strong gain, low noise, etc.). However, existing optical amplifiers generally fall short on one or more of these qualities.

For example, FOAs usually require a long length of doped optical fiber in order to obtain the desired amplification, and this length of fiber generally cannot be arranged into a compact shape (such as by tightly winding it into a coil) because the fiber has a minimum allowable bend radius to avoid damage. Thus, the FOAs generally comprise a loop of fiber which has a relatively large-diameter, making the FOAs larger and more cumbersome than may be desired in certain applications, such as datacenters or other applications where space may be more constrained. In addition, FOAs by their nature are not formed in a chip or wafer (instead being formed in an optical fiber) and thus they cannot be integrated into a photonic integrated circuit with other photonic components (a photonic integrated circuit referring to two or more photonic components which are integrated together in the same chip/wafer and which together form an optical circuit). The lack of integration of the FOA with the other optical components may result in increased size of the overall circuit and increased complexity in deployment of the circuit.

SOA, on the other hand, can generally be made small and are capable of being integrated into the same photonic integrated circuit as other photonic components. However, SOA tend to have high noise and some other performance drawbacks, and thus they may not be suitable for all applications. Furthermore, while it is possible to integrate SOA with other photonic components, this is generally very complicated and costly. In particular, photonic integrated circuits are often formed on silicon-based wafers (silicon wafers, silicon-on-insulator (SOI) wafers, etc.), as this allows for the leveraging of existing chip processing techniques and chip fabrication facilities which are commonly used in fabricating electronic integrated circuits (e.g., CMOS processing) and may also allow for the formation of electronic devices alongside the photonic components in the same chip. However, the III-V materials used in SOAs are generally not compatible with CMOS processing. Therefore, the III-V semiconductor layers generally need to be formed separately from the silicon-based wafer containing the other photonic components and then these two bodies are joined by techniques such as bonding or flip-chip processing. Not only are these chip joining techniques complicated and costly in their own rights, the incompatibility between the III-V materials and CMOS processing further complicates things, for example by requiring that additional expensive and complicated processes be employed to prevent contamination of the CMOS fabs (e.g., fabrication plant and equipment) during the joining process. Consequently, SOA photonic integrated circuits can be very costly and complicated to manufacture.

To address these and other issues, disclosed herein are various waveguide optical amplifiers formed from materials compatible with CMOS processing, such as silicon-based materials (e.g., silicon (Si), silicon oxide (SiO₂), silicon nitride (SiₓN_{y}), silicon oxynitride (SiₓO_{y}N_{z}), etc.). More specifically, each of the disclosed waveguides has a core portion defining an optical path and cladding at least partially surrounding the core portion, wherein the core portion is formed from three thin strips (layers) of CMOS-compatible materials that are layered/stacked together: two high-index strips and a low-index strip sandwiched between the two high-index strips. The high-index strips have higher refractive indexes than the low-index strip. In some examples, the strips are stacked relative to one another in a vertical direction (a direction perpendicular to a substrate on which the WOA is formed), in which case the strips may also be referred to herein as layers. In other examples, the strips are stacked relative to one another in a horizontal direction (parallel to the substrate). At least the low-index strip is doped with a dopant, such as a rare-earth-element (e.g., praseodymium (Pr), erbium (Er), ytterbium (Yb), etc.), which can be pumped to provide amplification. The waveguide optical amplifiers disclosed herein can be made very small, are capable of fabrication using simple and inexpensive fabrication processes (e.g., CMOS processing), and can be integrated into the same photonic integrated circuits as other photonic components without requiring the expensive and complicated techniques discussed above in relation to SOA. Furthermore, the layered structure of the core allows for extremely good optical confinement within the core, which allows the waveguide optical amplifiers disclosed herein to have very good amplification performance.

In particular, the waveguide optical amplifiers disclosed herein may provide amplification performance that is superior to that provided by alternative waveguide optical amplifiers which are formed using similar CMOS-compatible materials with similar dimensions, but with a different core structure, such as the waveguide optical amplifiers disclosed in U.S. patent application Ser. No. 18/488,308 and Ser. No. 18/627,078 the contents of each of which are incorporated herein by reference in their entirety. For example, an alternative waveguide optical amplifier may be formed with silicon nitride (SiₓN_{y}) or silicon oxynitride (SiₓO_{y}N_{z}) core doped with a rare-earth-element and at least partially surrounded by silicon dioxide (SiO₂) cladding. However, one challenge these alternatives face is that the core generally needs to be relatively thick to provide sufficient optical confinement, but this can result in a propensity for the layer to crack during manufacture. Furthermore, thick core layers such as those found in the alternative amplifiers are more difficult to implant with heavy elements, often requiring ion implanters with energies exceeding 1 MeV, which are not typically found in most CMOS fabs.

The waveguide optical amplifiers disclosed herein, on the other hand, may provide a mode profile which has a shape superior to that provided by the alternative amplifiers. This can allow the waveguide optical amplifiers disclosed herein to have various advantages over the alternative amplifiers, including thinner core layers (avoiding the difficulties described above in relation to thick core layers) and/or better amplification performance, as explained in more detail below.

In a waveguide, the electromagnetic field associated with the signal varies in intensity throughout different portions of the waveguide, and the “mode profile” refers to the distribution of these intensities along a given axis. In some contexts, a desirable shape for this mode profile is to have a relatively sharp and high peak within the amplifying portion of the core of the waveguide, with the peak having a relatively flat top. In other words, it can be desirable for the mode profile to be both relatively high and relatively constant (flat) throughout the amplifying portion of the core, and then to drop off sharply outside of the core.

The layered structure of the core in the waveguide optical amplifiers disclosed herein allows for its mode profile to have a shape similar to the desirable shape described above, i.e., the mode profile has a relatively flat-topped peak within the low-index strip and sharply drops off outside this strip. The alternative amplifiers, on the other hand, may have a mode profile which is shaped more like a gaussian curve (a “bell” shaped curve), which has a peak with a curved top and which decreases smoothly outside of the core.

These differences in mode profile shape can cause differences in amplifier performance characteristics which favor the waveguide optical amplifiers disclosed herein. For example, the mode profile differences allow the waveguide optical amplifiers disclosed herein to have superior confinement factors which greatly exceed (in some cases, by 3x or more) the confinement factors of the alternative waveguide optical amplifiers, assuming similar core dimensions. Or, to put the same point another way, the alternative waveguide optical amplifiers may need to have cores with much greater thicknesses (e.g., up to 3x thicker, in some cases) in order to achieve similar confinement factors as the waveguide amplifiers disclosed herein. The optical confinement factor is a measure of how well the electromagnetic field is contained within a waveguide's core, as opposed to leaking out into the adjoining portions. All other things being equal, a better confinement factor allows for greater gain (amplification) in a waveguide amplifier. Thus, the waveguide optical amplifiers disclosed herein can have superior amplification performance than the alternative amplifiers, assuming similar dimensions, or the amplifiers disclosed herein can be made smaller and with less expense than the alternative waveguide amplifiers while providing the same amplification performance.

Turning now to the figures, various devices, systems, and methods in accordance with aspects of the present disclosure will be described.

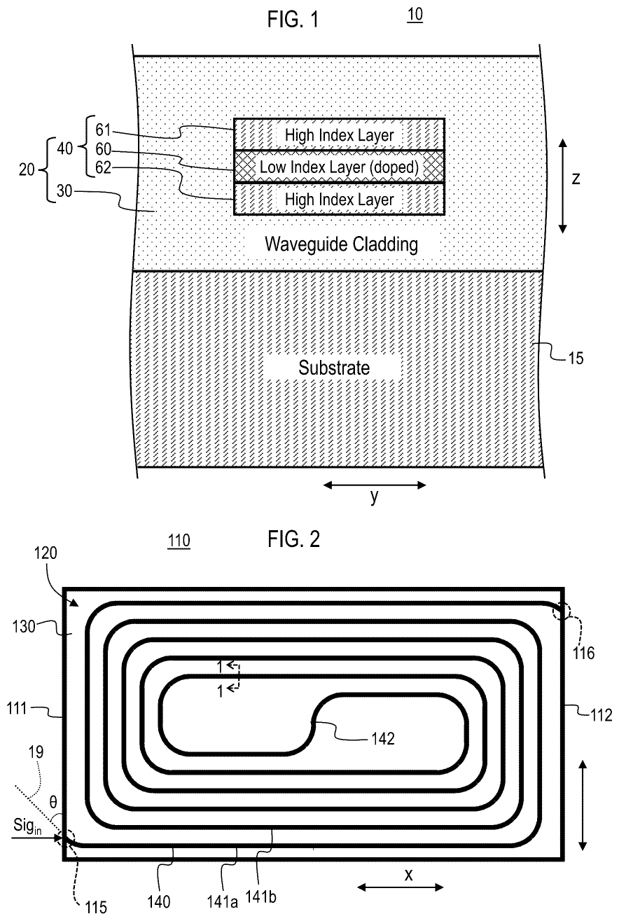

FIG. 1 schematically illustrates an example optical device 10 comprising a waveguide optical amplifier (WOA) 20. FIG. 1 shows a cross-section of a portion of the optical device 10, but it should be understood that FIG. 1 is schematic in nature and not intended to illustrate specific dimensions or other structural details accurately or to scale, unless otherwise noted herein. FIG. 1 does show the general positional relationships of material bodies (strips, layers, etc.) relative to one another, such as their relative layering order.

The optical device 10 comprises a substrate 15 and the WOA 20 formed on the substrate 15. In some examples, the substrate 15 and the WOA 20 are all formed from CMOS compatible materials, such as silicon-based materials for example. In an example, the substrate 15 comprises silicon (Si). In another example, the substrate may be glass, sapphire, or any other substrate. The substrate 15 may come in a variety of sizes, which may include various industry standard sizes. In one example, the substrate 15 may have a thickness of about 0.5 mm to 1.5 mm.

The WOA 20 comprises a waveguide formed from a waveguide cladding 30 and a waveguide core 40, with the cladding 30 at least partially surrounding the core 40 in a cross-section thereof (i.e., the cladding 30 abuts at least one side of the core 40). In FIG. 1, the cladding is shown fully surrounding the core 40 (i.e., abutting top, bottom, left, and right sides thereof) for purposes of illustration, but in various examples cladding material 30 could be partially or fully omitted from the regions adjacent one or more of these sides. In some examples, the cladding 30 is made from silicon-based materials. For instance, in some implementations the cladding 30 comprises silicon dioxide (SiO2). In FIG. 1, the cladding 30 appears as a unitary or monolithic layer for ease of illustration, but it should be understood that the cladding 30 could comprise multiple layers which could be similar or dissimilar to one another (including, potentially, having different materials). Furthermore, other materials could be placed around the core 40 in spaces which appear in FIG. 1 to be occupied by the cladding 30.

The core 40 comprises a layered structure with three material strips stacked or layered relative to one another in a vertical direction: a first high-index strip 61, a second high-index strip 62, and a low-index strip 60 sandwiched between the two high-index layers 61, 62. As used herein, “sandwiched between” refers to an arrangement in which one item is disposed between and abuts two other items, i.e., “X is sandwiched between A and B” means X is disposed between and abuts (contacts) A and B. These strips 60, 61, and 62 may also be referred to as layers herein, as in this example they form or occupy different vertical layers in the device 10. The high-index layers 61 and 62 have refractive indexes n₁ and n₂, respectively, which are both higher than a refractive index n₀ of the low-index layer 60. Refractive indices may vary based on the wavelength of light, and thus comparisons herein between refractive indices assume the refractive indices being compared are for same wavelength of light. In some examples, the refractive indices mentioned herein are for a wavelength of light which falls in the range of wavelengths with which the optical device is configured to operate, which may depend on the type of dopant included in the core 40. For example, wavelengths commonly used in various optical devices range from about 970 nm to about 1600 nm, as explained in greater detail below.

The low-index layer 60 is doped with rare-earth element atoms, which allow for the amplification of light, as will be described in greater detail below. In some examples, the layers 60, 61, and 62 are formed from various silicon-based materials, such as silicon, silicon nitride (SiₓN_{y}), and/or silicon oxynitride (Si₍ₓ₎O_{(y)}N_{(z)}). In some examples, the high-index layers 61 and 62 are formed from the same material as one another, in which case n₁=n₂. In other examples, the high-index layers 61 and 62 can be formed from different materials, in which case n₁ and n₂ may be different from one another (but both will be higher than n₀). In some examples, the materials and the vertical thicknesses of the layers 60, 61, and 62 may be selected so as to provide a desired mode profile.

In some examples, the first and second high-index layers 61 and 62 are both silicon layers and the low-index layer 60 is a silicon nitride (e.g., Si₃N₄) layer doped with rare-earth elements. In such examples, the refractive indices n₁=n₂ may be that of silicon, which is about 3.5, while the refractive index n₃ may be that of silicon nitride, which is about 2.0, both assuming wavelengths in the range of about 970 nm to 1600 nm.

In some examples, the first and second high-index layers 61 and 62 are both silicon nitride (e.g., Si₃N₄) layers and the low-index layer 60 is a silicon oxynitride (SiₓO_{y}N_{z}) layer doped with rare-earth elements. In such examples, the refractive indices n₁=n₂ may be that of silicon nitride, which is about 2.0, while the refractive index n₃ may be that of silicon oxynitride, which ranges from about 1.45 to about 2.0 (depending on the concentrations of oxygen and nitrogen), both assuming wavelengths in the range of about 970 nm to 1600 nm.

In some examples, the first and second high-index layers 61 and 62 are both silicon nitride layers and the low-index layer 60 is a metal oxide (Al₂O₃, HfO₂, etc.) layer doped with rare-earth elements. In such examples, the refractive indices n₁=n₂ may be that of silicon nitride, which is about 2.0, while the refractive index n₃ may be that of the selected metal oxide, such as about 1.7 for Al₂O₃ as one example, both assuming wavelengths in the range of about 970 nm to 1600 nm.

Various other combinations of materials can be used for the high and low-index layers 60, 61, and 62, as would be apparent to those of ordinary skill in the art after having read this disclosure. In some examples, the materials for the high and low-index layers 60, 61, and 62 may be CMOS compatible materials, which may include, but is not necessarily limited to, silicon-based materials.

It should be noted that the terms “high-index” and “low-index” are defined herein on a per core basis relative to the refractive indices of the stacked strips/layers of that core (i.e., layers 60, 61, and 62). Thus, a material which is considered “high-index” in one core may be considered “low-index” in another core. More specifically, in a core with three vertically stacked layers, the highness or lowness of the refractive indexes n₁ and n₂ of the top and bottom layers (i.e., layers 61 and 62) are judged relative to the refractive index n₀ of the middle layer (i.e., layer 60), and vice versa. Thus, if in a given three-layer core, the refractive indexes n₁ and n₂ of the bottom and top layers (e.g., layers 61 and 62) are both greater than the refractive index n₀ of the middle layer (e.g., layer 60), then the top and bottom layers may be considered as “high-index” layers and the middle layer as a “low-index” layer in that given core. The same is true for a core comprising horizontally stacked strips, except that references to “top layer” and “bottom layer” in the foregoing description would instead be replaced with “left strip” and “right strip.” As one example of how the same material could be considered to be a “low-index” material in one core but a “high-index” material in another core, consider the following: if a first core has a layered structure comprising silicon (bottom), silicon nitride (middle), and silicon (top), then the silicon nitride layer would be considered as a low-index layer in the first core because silicon has a higher refractive index than silicon nitride, but in a second core which has a layered structure comprising silicon nitride (bottom), silicon oxynitride (middle), and silicon nitride (top), the silicon nitride layers would now be considered as high-index layers in that core because silicon nitride has a refractive index higher than silicon oxynitride.

In some examples, the doping element used to dope the low-index layer 60 may be erbium (Er), which can allow for the WOA 20 to amplify light in the C-band (1530-1565 nm), when pumped with 1480 nm pump laser light. In other examples, the doping element may be praseodymium (Pr), which can allow for the WOA 20 to amplify light in the O-band (1260-1360 nm), when pumped with 980 nm pump laser light. In other examples, the doping element may be bismuth (Bi), which can allow for the WOA 20 to amplify light in the E-band (1360-1460 nm), when pumped with 1310 nm pump laser light. In other examples, the doping element may be thorium (Th), which can allow for the WOA 20 to amplify light in the S-band (1460-1530 nm), when pumped with 1400 nm pump laser light. In some examples, the core 40 may also have additional dopants (e.g., rare-earth elements) co-implanted along with the aforementioned elements. For example, in some instances Pr may be implanted to act as the primary light amplifier and additional rare earth dopants may be co-implanted with the Pr dopants to act as a sensitizer and improve the pumping efficiency of the Pr atoms, or to achieve some other desired effect—for example, a suitable material for co-implanting with the Pr dopant is ytterbium (Yb).

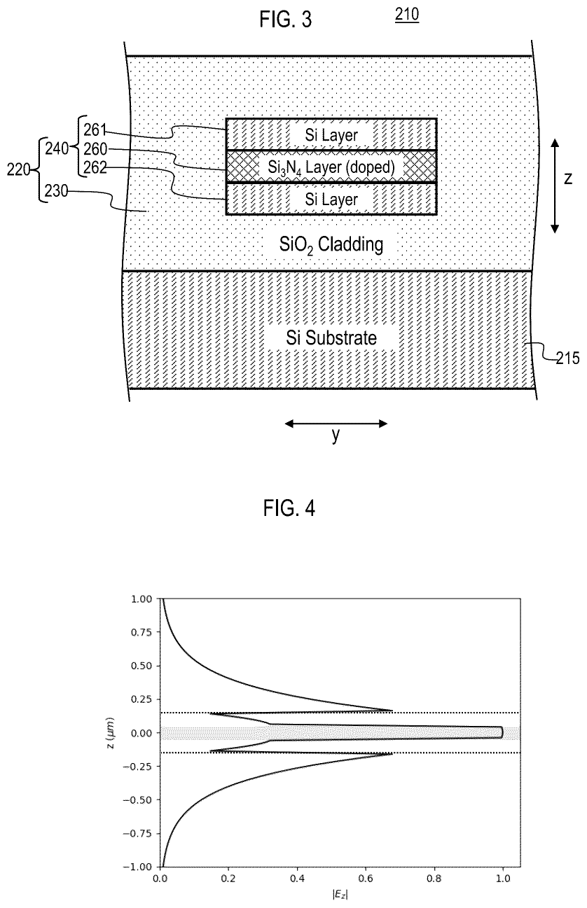

In FIG. 1, the waveguide of the WOA 20 appears as if in a buried channel configuration (i.e., the cladding 30 surrounds the core 40 on top, bottom, and both lateral sides thereof) for ease of illustration, but FIG. 1 is schematic in nature and not intended to depict the shapes or other structural details of the components of the WOA 20. Thus, the waveguide of the WOA 20 can have any waveguide configuration as long as that configuration includes the high and low-index layers 60, 61, and 62 stacked on one another as described above. Non-limiting examples of other waveguide configurations which the WOA 20 could use include: the buried channel configuration; a ridge configuration in which cladding 30 abuts the bottom side of the core 40 with other sides being open to air; a strip-loaded configuration in which the cladding 30 abuts the bottom side and part of the top side of the core 40; a rib configuration in which the core 40 has a relatively wide bottom portion (e.g., high-index layer 62) with a relatively narrow ridge like portion (e.g., low-index layer 60 and high-index layer 61) on top of the wide bottom portion, wherein the cladding 30 abuts at least the bottom side of the core 40; or any other desired waveguide configuration. Furthermore, in FIG. 1, the high and low-index layers 60, 61, and 62 all appear with similar widths (y-axis) and thicknesses (z-axis) and with uniform flat surfaces for ease of illustration, but FIG. 1 is not intended to depict structural details such as the dimensions of the layers or surface features thereof, and one or more of the layers 60, 61, and 62 may have different dimensions than one or more of the other layers 60, 61, or 62 and/or may include surface features such as trenches, ridges, or other surface features. Non-limiting examples of some of the aforementioned configurations of the WOA 20 are shown in FIGS. 3, 5, and 9-12, which will be described in greater detail below.

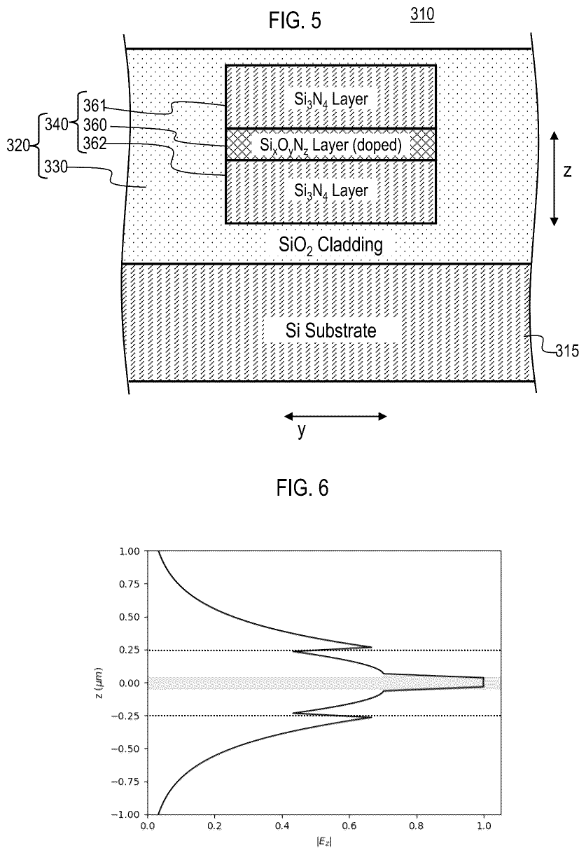

The WOA 20 may produce a mode profile which is relatively flat. For example, FIGS. 4 and 6 illustrate two vertical mode profiles for two examples of the WOA 20, which will be described in greater detail below with reference to FIGS. 3 and 5. In both FIGS. 4 and 6, the z-axis indicates position along a vertical dimension of the WOA with the zero-point of the z-axis being at a center of the low-index layer. The vertical dimension is perpendicular to a face of the substrate and parallel to the direction in which the layers are stacked in the WOA, and is indicated in the Figures by the axis labeled “z”. In each of FIGS. 4 and 6, the shaded region corresponds to span of the low-index layer, whereas the dotted lines indicate locations of a top of the upper high-index layer and a bottom of the lower high-index layer. As can be seen in FIGS. 4 and 6, both of these examples of the WOA 20 provide a mode profile which has its peak within the low-index layer and which is relatively flat within that region, meaning that the mode is relatively constant within the low-index layer and then drops off sharply at the boundaries between the layer and the adjoining high-index layers. Flat mode profiles such as these allow for the WOA 20 have a relatively high confinement factor and good gain.

In some examples, optical device 10 may be formed using silicon-on-insulator (SOI) fabrication techniques, with the substrate 15 forming a so-called handle of the wafer and at least a portion of the cladding 30, including the portion sitting below the core 40, being formed from a so-called buried oxide (BOX) layer of the wafer. In some of these examples, the handle (e.g., substrate 15) may be formed from silicon and the BOX (e.g., lower portion of cladding 30) may be formed from silicon dioxide SiO₂. In some examples, one or more other devices (optical, electrical, or electrooptical), may also be formed on the BOX in addition to WOA 20, with the WOA 20 and the other device(s) being integrated together as part of the same photonic integrated circuit. Thus, in some examples, the entirety of the BOX layer does not necessarily form the cladding 30 of WOA 20, but instead only a portion of the BOX layer forms the cladding 30 of WOA 20 and other portions of the BOX layer may form parts of other devices.

Turning to FIG. 2, an example optical device 110 will be described. FIG. 2 shows a top-down schematic view of the device 110. The optical device 110 is one example implementation of the optical device 10, and thus the optical device 110 includes components which correspond to components of the optical device 10 already described above. These corresponding components are given similar reference numbers having the same last two digits, such as 40 and 140. The descriptions above of components of the optical device 10 are applicable to the corresponding components of the optical device 110 unless otherwise noted, and thus duplicative descriptions of these corresponding components will be omitted.

The optical device 110 comprises an input port 115 and an output port 116, with the waveguide of the WOA 120 defining an optical path extending between these ports 115 and 116. The ports 115 and 116 are configured to be optically coupled (and in some cases, physically connected) to an input optical interconnect and an output optical interconnect, respectively. These input and output optical interconnects may be, for example, optical fibers. Thus, an input light signal SIGᵢₙ carried on the input optical interconnect may be introduced to the core 140 of the WOA 120 via the input port 115, subsequently amplified as it passes through path defined by the core 140, and then the amplified output light signal SIGₒᵤₜ passes out from the optical device 110 to the output optical interconnect via the output port 116. The signal light SIGᵢₙ comprises light which has been modulated to carry (encode) information, and it is the amplification of this signal light SIGᵢₙ which is a purpose of the WOA 120. Note that other light, such as pump laser light, may also pass through the WOA 120, but this other light is not shown in FIG. 2. In some cases, the other light (e.g., pump light) may enter and exit the WOA 120 via the same ports 115 and 116 which carry the signal light. In other cases the optical device 10 may have additional ports (not illustrated) to allow for the entry and exit of the other light.

The ports 115 and 116 may comprise edge couplings with an external lens or turning mirror (or lens), edge couplings with spot size transformers (e.g., V-grooves may be etched into the silicon substrate to facilitate physical attachment of the optical fiber at the ports 115 and 116), surface couplings with a grating coupler or on-chip turning mirror (or lens), or any other known form of optically coupling optical fibers to optical devices. In the example illustrated in FIG. 2, the input port 115 and outlet port 116 are disposed on opposite edges of the optical device 110, namely on a first edge 111 and a second edge 112, respectively. In other examples (not illustrated), the input and outlet ports may be arranged differently, such as on two different sides that are not opposite one another or on the same side as one another. In some examples, the waveguide core 140 is arranged such that, where the core 140 meets the input port 115 or outlet port 116, the direction of extent 19 of the core 140 is at an acute angle θ relative to the edge 111 or 112 of the optical device 110. More specifically, in some examples, 0°<θ<50°. This can help to reduce back-reflections and suppress on-chip lasing.

In FIG. 2, the path that the core 140 of the WOA 120 follows has a double spiral shape. As used herein, a double spiral is a shape having two spiral portions: a first portion that spirals inward towards a center and a second portion that spirals outward from the center, with the two portions being joined together at a change-over point (generally near a center of the shape). As shown in FIG. 2 the core 140 can form a double-spiral optical path comprising a first spiral portion 141a that spirals inward from the input port 115 toward the change-over point 142, and a second spiral portion 141b that spirals outward from the change-over point 142 to the output port 116. In some examples, the bend radius of the core 140 along this double spiral path may be maintained at least at 70 μm or greater (i.e., less than or equal to 0.2 dB/cm or 0.01 dB/90 deg bend). Wider waveguides, and larger bend radius or Euler bends with appropriate adiabatic transitions can reduce the straight and bent waveguide propagation losses, respectively.

Spiral as used herein refers to a path that circles repeated around a central point forming successively nested loops around that point, with each of the loops (except for an outermost loop) being contained within another one of the loops. In other words, the loops get progressively closer to the central point if the path is traversed in one direction or progressively further from the center point if the path is traversed in the opposite direction. These loops of the spiral do not necessarily have to be circular or even rounded, and may have straight portions. Moreover, although the loops of the illustrated double spiral have a generally rectangular shape (with rounded corners), any other desired shape may be used, such as circular, elliptical, trapezoidal, pentagonal, etc.

Although a double-spiral optical path of the core 140 is illustrated in FIG. 2, this is just one example of an optical path that the core could follow in various implementations of the optical device 10. In other example implementations of the optical device 10, the core 40 could follow a different optical path, while other aspects of the device may be similar to those of the device 110 described above. For example, the core 40 could follow a straight linear path (not illustrated), a serpentine path, a double serpentine path (e.g., extending in a serpentine fashion in one direction from one region to a second region and then doubling back at the second region to proceed in a serpentine fashion back to the original starting region) (not illustrated), or any other desired path. In particular, the core 40 could follow any of the optical paths disclosed in in U.S. patent application Ser. No. 18/488,308 and Ser. No. 18/627,078, as some examples.

Furthermore, FIG. 2 illustrates the optical device 110 as having one WOA 120, which is an example of the WOA 20, but this is merely one example of how the optical device 10 could be implemented. In various other example implementations of the optical device 10, there may be one or more other optical components integrated into the same photonic integrated circuit with the WOA. These other optical components may include: one or more additional instances of the WOA 20 (which may be arranged in a 1-D or 2D array or interleaved), wavelength division multiplexing (WDM) couplers, polarization splitter/rotators, or any other desired optical components. In addition, in various example implementations of the optical device 10, there may be one or more electrical components integrated into the same photonic integrated circuit with the WOA 20. In particular, implementations of the optical device 10 could include any of the optical device configurations disclosed in in U.S. patent application Ser. No. 18/488,308 and Ser. No. 18/627,078, for example, except that the core 40 disclosed herein may be substituted for some or all of the cores disclosed in those applications as appropriate.

FIGS. 3 and 5 illustrate optical devices 210 and 310, which are two examples of the optical device 10. Thus, the optical devices 210 and 310 include components which correspond to components of the optical device 10 already described above. These corresponding components are given similar reference numbers having the same last two digits, such as 40 and 240. The descriptions above of components of the optical device 10 are applicable to the corresponding components of the optical devices 210 and 310 unless otherwise noted, and thus duplicative descriptions of these corresponding components will be omitted.

The optical device 210 shown in FIG. 3 includes a silicon substrate 215 and a WOA 220 formed thereon. The WOA 220 includes silicon dioxide (SiO₂) cladding 230 formed on the substrate 215 and a core 240. The core 240 is surrounded, in cross-section, on all sides thereof by the cladding 230 in a buried channel configuration. The core 240 comprises a silicon nitride (Si₃N₄) layer 260, which is an example of low-index layer 60, and two silicon layers 261 and 262, which are examples of high-index layers 61 and 62, respectively. These layers 260, 261, and 262 are stacked/layered atop one another as shown in FIG. 3 and as described above. In some examples, each of the layers 260, 261, and 262 are about 0.1 μm thick (along the z-axis). In some examples, each of the layers 260, 261, and 262 is about 1.0 μm wide (along the y-axis). Thus, in some examples, the layers 260, 261, and 262 have an aspect ratio of about 10, i.e., they are about ten times as wide as they are thick. In other examples, the layers 260, 261, and 262 may be narrower or wider. The WOA 220 may produce a mode profile which has a relatively flat top. For example, FIG. 4 shows the mode profile of an implementation of the WOA 220 in which the layers 260, 261, and 262 are about 0.1 μm thick, and this mode profile has a very flat top which allows for a confinement factor of about 47%.

The optical device 310 shown in FIG. 5 includes a silicon substrate 315 and a WOA 320 formed thereon. The WOA 320 includes silicon dioxide (SiO₂) cladding 330 formed on the substrate 315 and a core 340. The core 340 is surrounded, in cross-section, on all sides thereof by the cladding 330 in a buried channel configuration. The core 340 comprises a silicon oxynitride (SiₓO_{y}N_{z}) layer 360, which is an example of low-index layer 60, and two silicon nitride (e.g., Si₃N₄) layers 361 and 362, which are examples of high-index layers 61 and 62, respectively. These layers 360, 361, and 362 are stacked/layered atop one another as shown in FIG. 4 and as described above. In some examples, the low-index silicon oxynitride layer is about 0.1 μm thick (along the z-axis), while the high-index silicon nitride layers 361 and 362 are about 0.2 μm thick (along the z-axis). In some examples, each of the layers 360, 361, and 362 is about 1.0 μm wide (along the y-axis). Thus, in some examples, the layer 360 has an aspect ratio of about 10 and the layers 361 and 362 have aspect ratios of about 5. In other examples, the layers 260, 261, and 262 may be narrower or wider. The layers 360, 361, and 362 may have any desired width. The WOA 320 may produce a mode profile which has a relatively flat top. For example, FIG. 6 shows the mode profile of an implementation of the WOA 320 in which the layer 360 is 0.1 μm thick and the layers 361 and 362 are 0.2 μm thick, and this mode profile has a very flat top which allows for a confinement factor of about 22%.

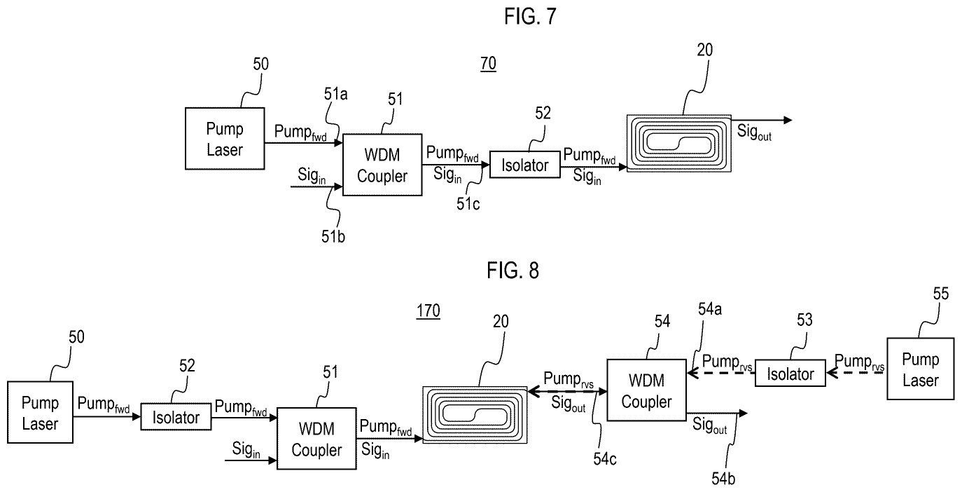

Turning to FIGS. 7 and 8, the operation of the optical device WOA 20 will be described in greater detail. FIGS. 7 and 8 illustrate optical systems 70 and 170 comprising the WOA 20. Note that, FIGS. 7 and 8 show the WOA 20 with a spiral optical path merely for the sake of illustration, but the WOA 20 can have any optical path as already noted above.

The optical system 70 shown in FIG. 7 comprises a pump laser 50, a wavelength division multiplexing (WDM) coupler 51, one or more isolators 52, and the WOA 20. In some examples, a wavelength division multiplexing (WDM) coupler 51 and/or the isolators 52 may be provided as part of the same photonic integrated circuit as the WOA 20—for example, they may be formed on the same substrate 15. Various examples of how a WDM coupler (and other components) may be integrated into a same photonic integrated circuit as a WOA are disclosed in U.S. patent application Ser. No. 18/627,078, and the same approaches could be used with the WDM coupler 51 and the WOA 20. In other examples, the WDM coupler 51 and/or the isolators 52 may be provided separate from the WOA 20 (i.e., not part of the same chip) and they may be optically connected by optical interconnects, such as optical fibers.

The pump laser 50 produces a pump light Pump_{fwd}, which is configured to be absorbed by and excite the dopant atoms in the core 40 of the WOA 20 to an excited state. For example, in instances where the dopant is erbium (Er), the pump light Pump_{fwd} may be laser light having a wavelength of approximately 1480 nm. Other wavelengths of pump laser light may be used in examples where other dopants are used, as explained above.

The pump light Pump_{fwd} is input to the WDM coupler 51 via optical interconnect 51a, which may be an optical fiber or other optical interconnect. The WDM coupler 51 may also receive the signal light Sigᵢₙ via a second optical interconnect 51b, which may be an optical fiber or other optical interconnect. The WDM coupler 51 then combine these signals into one combined light signal which is output to the isolator 52 or the WOA 20 via optical interconnect 51c. In some examples in which the WDM coupler 51 is integrated with the WOA 20 into the same chip, the optical interconnect 51c may be formed from a waveguide which is on the same substrate as the WOA 20 and which is coupled to the waveguide for the WOA 20 (in some cases, they may be part of the same overall waveguide structure, although in some cases the optical interconnect 51c may comprise an undoped portion of the waveguide). In examples in which the WDM coupler 51 and the WOA 20 are separate discrete components, the optical interconnect 51c may be an optical fiber or other interconnect.

The isolator 52 prevents any light traveling in a reverse direction (i.e., a direction opposite the direction of the Sigᵢₙ light) from passing the isolator 52. Such light traveling in a reverse direction might include light reflected from a downstream component or spontaneous emission noise from the WOA 20. The isolator 52 allows light traveling in the forward direction (rightward in the figure) to pass. In some examples, the isolator 52 could be positioned between the pump laser 50 and WDM coupler 51. In some examples, a second isolator (not illustrated) is positioned on the other side of the WOA 20 and is arranged to block any reverse direction light coming from components downstream of the WOA 20. In some examples, the isolator 52 can be omitted.

The combined Pump_{fwd}/Sigᵢₙ from the isolator 52 is then input to the WOA 20. The pump light Pump_{fwd} is absorbed by the dopant atoms in the core 40 of the WOA 20, exciting electrons thereof to an excited state. The signal light Sigᵢₙ then interacts with these excited-state dopant atoms, causing the dopant atoms to emit photons (light) via stimulated emission. These emitted photons have the same wavelength and travel in the same direction as the signal light which stimulated their emission, and thus the emitted photons join with and increase the intensity of the signal light Sigᵢₙ. After emitting a photon, the excited state electrons drop to an intermediate state and quickly decay to the ground state by emitting phonons. The electrons of the dopant atoms are then re-excited by the pump light Pump_{fwd}, which may be continually passed through the WOA 20, and the process described above repeats. Gain is achieved when population inversion between excited and intermediate states of the dopant atoms exceed a threshold set by the on-chip loss.

In the system 70, laser light is pumped only in the forward direction through the input side of the WOA 20. However, in some implementations, laser light can be pumped in both the forward and the reverse directions through input and outlet sides of the WOA 20, as shown in the optical system 170 of FIG. 8. This may be done to ensure that the full length of the WOA 20 is excited. If only the forward pumping is used as in FIG. 7, then it may be possible for all of the forward pump light Pump_{fwd} to be absorbed prior to reaching the far end of the WOA 20, resulting in the dopant atoms in that region not being excited, thus potentially losing out on some amplification potential. In contrast, in the optical system 170 of FIG. 8, the reverse direction pump light Pumpᵣᵥₛ ensures that the end portion of the WOA 20 near the outlet thereof is also fully excited, thus maximizing amplification.

The optical system 170 is the same as the optical system 70 except that the optical system 170 has an additional set of optical components for providing reverse pump light Pumpᵣᵥₛ on the output side of the WOA 20, in addition to the set of components already provided on the input side to provide the forward pump light Pump_{fwd}. Specifically, in addition to the components of the system 70, the system 170 further comprises another pump laser 55, another isolator 53, and another WDM coupler 54. In some examples, the WDM coupler 51, WDM coupler 54, isolators 52, and/or the isolators 53 may be provided as part of the same photonic integrated circuit as the WOA 20, in the same manner as described above. In other examples, some or all of these components may be provided separate from the WOA 20 (i.e., not part of the same chip) and they may be optically connected by optical interconnects, such as optical fibers.

The pump laser 55 may be provided to provide reverse pump light Pumpᵣᵥₛ flowing in a reverse direction through the WOA 20. In this example, a second WDM coupler 54 may be provided between the pump laser 55 and the WOA 20, which is configured to direct Pumpᵣᵥₛ into the outlet side of the WOA 20. The reverse pump light Pumpᵣᵥₛ enters the WDM coupler 54 via optical interconnect 54a, which may be, for example, an optical fiber or other interconnect. The reverse pump light Pumpᵣᵥₛ is then coupled by the WDM coupler 54 into the optical interconnect 54c. Note that this optical interconnect 54c is the same one which carries the output signal Sigₒᵤₜ out of the WOA 20. However, the pump light Pumpᵣᵥₛ and the output signal Sigₒᵤₜ will travel in opposite directions along this interconnect 54c, as indicated by the arrows in FIG. 4. In examples where the WDM coupler 54 and WOA 20 are integrated into the same chip, the optical interconnect 54c may be formed from a waveguide which is on the same substrate as the WOA 20 and which is coupled to the waveguide for the WOA 20 (in some cases, they may be part of the same overall waveguide structure, although in some cases the optical interconnect 54c may comprise an undoped portion of the waveguide). In other examples, the optical interconnect 54c could be a separate discrete interconnect, such as an optical fiber. The WDM coupler 54 receives the output signal Sigₒᵤₜ from this optical interconnect 54c and outputs the output signal Sigₒᵤₜ to an output path via the optical interconnect 54b.

A second isolator 53 may also be provided between the WDM coupler 54 and the pump laser 55 and arranged to block light traveling in the forward direction (i.e., rightward in the figure).

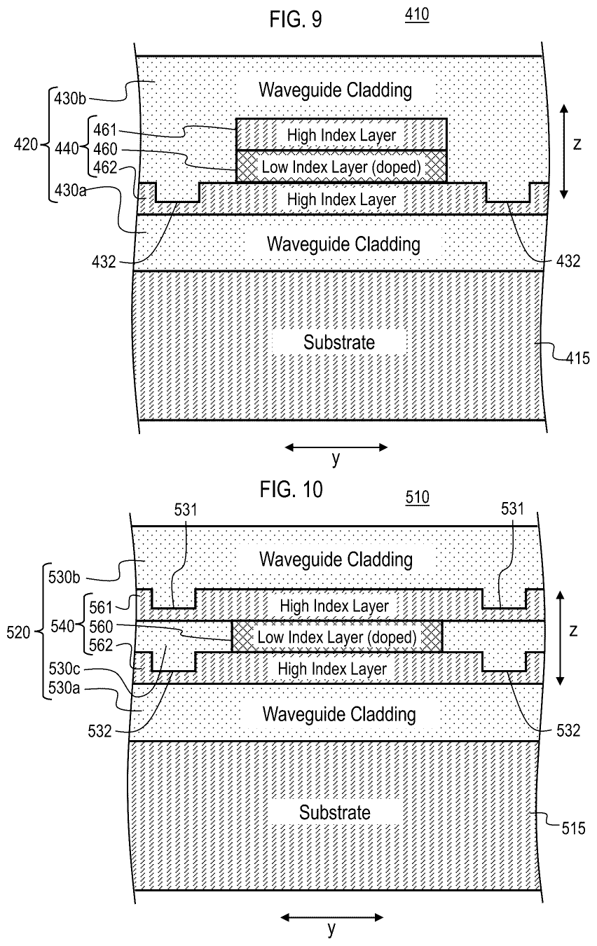

Turning now to FIGS. 9-12, example optical devices 410, 510, 610, and 710 and will be described. These optical devices comprise example configurations, implementations, variations, or modifications of the optical device 10 described above, and each has at least some components that are the same as or similar to components described above in relation to the optical device 10. In particular, each of these optical devices has at least one WOA, which may be an implementation example of the WOA 20 described above. Unless otherwise noted (or otherwise illustrated), or unless it would be logically contradictory, the descriptions of the components of the optical device 10 above are also applicable to any of the similar components of the other example optical devices described below, and thus duplicative descriptions of these similar components is omitted below. The components of the optical devices described below which are the same as or similar to the above-described components are given reference numbers having the same last two digits (e.g., 40 and 440).

FIG. 9 illustrates an example optical device 410, which is an example of the optical device 10. The optical device 410 includes a substrate 415 and a WOA 420 formed thereon. The WOA 420 includes cladding 430a, 430b formed on the substrate 415 and a core 440 formed on/in the cladding. The core 440 includes a bottom high-index layer 462, a top high-index layer 461, and a middle low-index layer 460 sandwiched between the layers 462 and 461. Materials and configurations for the various components of the optical device 410 may be as described above in relation to the optical device 10 and 110, unless otherwise specified.

A notable characteristic of the WOA 420 is that the bottom high-index layer 462 extends laterally (in y-axis dimension) beyond lateral edges of the low-index layer 460 and top high-index layer 461, making the bottom high-index layer 462 wider than the other layers 460 and 461. Furthermore, in some examples, the bottom high-index layer 462 may include trenches 432 formed at locations spaced laterally outward from the layers 460 and 461, as shown in FIG. 9. The trenches 432 may help to prevent light from leaking laterally out of the waveguide.

The trenches 432 in FIG. 9 are shown as being recessed downward from a top face of layer 462, but in some examples trenches 432 could be recessed upwards from a bottom face of layer 462. The precise locations of the trenches 432 along the y-axis relative to the layers 460 and 461 are not limited to the locations shown; for example, the trenches 432 could be located closer to the layers 460 and 461 or farther from the layers 460 and 461. The cross-sectional shape and dimensions of the trenches 432 is not limited to the that shown, and could include any shape (e.g., rectangular, square, rounded (e.g. semi-circular), triangular or V-shaped, etc.), any width, and any depth (limited only by the thickness of the layer 462). In addition, although in some examples only one trench 432 is provided on each side of the layers 460 and 461 (resulting in two trenches 432 total), as illustrated in FIG. 9, in other examples multiple trenches 432 could be provided on each side of the layers 460 and 461.

The core 440 is at least partially surrounded, in cross-section, by the cladding 430a, 430b, with cladding 430a positioned below the bottom high-index layer 462 and cladding 430b positioned above the bottom high-index layer 462. The cladding 430a abuts a bottom side of the layer 462. The cladding 430b abuts part of the top side of the layer 462, the top side of the layer 461, and lateral sides of the layers 460 and 461. In some examples, some or all of the top cladding 430b may be omitted, leaving air abutting the top and/or lateral sides of the core 440. For example, in some implementations the regions laterally adjacent the layers 460 and 451 may be left open to air and a strip of cladding 430b may be positioned on a top side of the layer 461. In some examples, the cladding 430b is all one type of material, while in other examples the cladding 430b may be formed from different layers of different materials—for example, the portion of the cladding 430b adjacent the lateral sides of the layers 460 and 461 may be one material while the portion of the cladding 430b atop the layer 461 may be a different material. In some examples, at least the portion of the cladding 430b adjacent the lateral sides of the layer 460 may have a refractive index less than the refractive index of the layer 460 to prevent light leakage into the cladding 430b. In examples which include the trenches 432, the trenches 432 may be filled with the same material as the cladding 430b (e.g., SiO₂) or with some other material (e.g., air, SiₓO_{y}N_{z}).

In some examples, the lateral sides (not visible in FIG. 9) of the bottom high-index layer 462 are not abutted by any cladding. In other examples, the lateral sides of the bottom high-index layer 462 may be abutted by cladding. In some examples, the material layer which forms the bottom high-index layer 462 may extend in the y-axis direction across the fully width of the device 410, and in some of these examples, this same material layer may form part of multiple devices (e.g., the same material layer may form the bottom high-index layer 462 of multiple WOA 420 formed on the same substrate 415). In other examples, the bottom high-index layer 462 may extend only a predetermined distance laterally beyond the edge of the other layers 460 and 461.

FIG. 10 illustrates an example optical device 510, which is an example of the optical device 10. The optical device 510 includes a substrate 515 and a WOA 520 formed thereon. The WOA 520 includes cladding 530a, 530b, and/or 530c formed on the substrate 515 and a core 540 formed on/in the cladding. The core 540 includes a bottom high-index layer 562, a top high-index layer 561, and a middle low-index layer 560 sandwiched between the layers 562 and 561. Materials and configurations for the various components of the optical device 510 may be as described above in relation to the optical device 10 and 110, unless otherwise specified.

A notable characteristic of the WOA 520 is that the bottom and top high-index layers 561 and 562 both extend laterally (in y-axis dimension) beyond lateral edges of the low-index layer 560, making the bottom and top high-index layers 561 and 562 wider than the low-index layer 560. Furthermore, in some examples, the bottom high-index layer 562 may include trenches 532 formed at locations spaced laterally outward from the layer 560, as shown in FIG. 10. Furthermore, in some examples, the top high-index layer 561 may include trenches 531 formed at locations spaced laterally outward from the layer 560, as shown in FIG. 10. The trenches 531 and 532 may help to prevent light from leaking laterally out of the waveguide. The trenches 531 and 532 are shown in FIG. 10 as being recessed downward from top faces of the layers 561 and 562, respectively, but in some examples trenches 531 and/or 532 could be recessed upwards from bottom faces of layers 561 and/or 562. In addition, the trenches 531 and/or 532 could have locations, shapes, dimensions, and/or numbers different than those shown, in a similar manner as described above with respect to the trenches 432. Furthermore, trenches 531 do not necessarily need to be the same in terms of form, number, or locations as the trenches 532—e.g., one could be recessed downward while the other is recessed upward, one could be located closer to the layer 560 than the other, etc.

The core 540 is at least partially surrounded, in cross-section, by the cladding 530a, 530b, and/or 530c, with cladding 530a positioned below the bottom high-index layer 562, cladding 530b positioned above the top high-index layer 561, and cladding 530c positioned therebetween. The cladding 530a abuts the bottom side of layer 562. The cladding 530b abuts the top side of the layer 561. The cladding 530c abuts part of the top side of layer 562, part of the bottom side of layer 561, and lateral sides of the layer 560. In some examples, some or all of the top cladding 530b may be omitted, leaving air abutting the top side of layer 561. In some examples, some or all of the cladding 530c may be omitted, leaving air abutting the lateral sides of layer 560. In some examples, the cladding 530a, 530b, and/or 530c are all formed from one type of material, while in other examples the cladding 530a, 530b, and/or 530c may be formed from different layers of different materials. In some examples, at least the cladding 530c may have a refractive index less than the refractive index of the layer 560 to prevent light leakage into the cladding 530b. In examples which include the trenches 531 and 532, the trenches 531 and 532 may be filled with the same materials as the cladding 530b and 530c, respectively, or with some other material (e.g., air, SiₓO_{y}N_{z}).

In some examples, the lateral sides (not visible in FIG. 10) of the bottom and/or top high-index layers 562 and/or 561 are not abutted by any cladding. In other examples, the lateral sides of the bottom and/or top high-index layers 562 and/or 561 may be abutted by cladding. In some examples, the material layer which forms the bottom high-index layer 562 may extend in the y-axis direction across the fully width of the device 510, and in some of these examples, this same material layer may form part of multiple devices (e.g., the same material layer may form the bottom high-index layer 562 of multiple WOA 520 formed on the same substrate 515). In other examples, the bottom high-index layer 562 may extend only a predetermined distance laterally beyond the edges of the layer 560. In some examples, the material layer which forms the top high-index layer 561 may extend in the y-axis direction across the fully width of the device 510, and in some of these examples, this same material layer may form part of multiple devices. In other examples, the top high-index layer 561 may extend only a predetermined distance laterally beyond the edges of the layer 560. In some examples, the high-index layers 561 and 562 may have a same width (z-axis dimension) as one another, while in other examples they may have different widths.

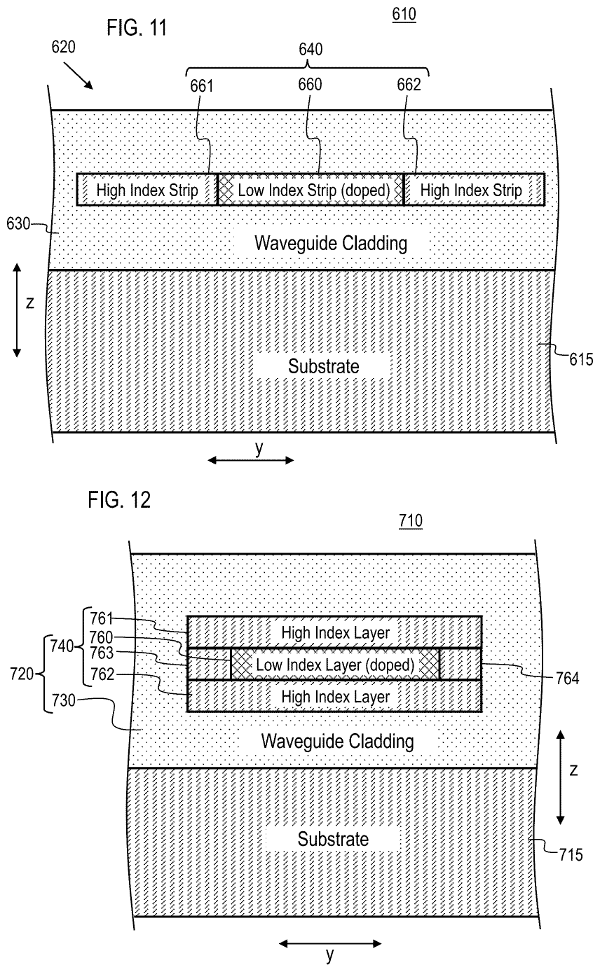

FIG. 11 illustrates an example optical device 610, which is a variation on the optical device 10. The optical device 610 includes a substrate 615 and a WOA 620 formed thereon. The WOA 620 includes cladding 630 formed on the substrate 615 and a core 640 formed on/in the cladding. The core 640 includes a high-index strips 662, a high-index strip 661, and a low-index strip 660 sandwiched between the strips 662 and 661. Materials and configurations for the various components of the optical device 610 may be as described above in relation to the optical device 10 and 110, unless otherwise specified.

The WOA 620 may be similar to the WOA 20 in that both have a three-strip core including two high-index strip and one low-index strip which are stacked/layered together with the low-index strip in between the high-index strips. However, the WOA 620 differs from the WOA 20 in that in the WOA 620 the strips of its core 640 are stacked relative to one another in a horizontal (y-axis) direction rather than in a vertical (z-axis) direction as in the WOA 20. In other words, in the WOA 620, the strips 660, 661, and 662 are all positioned within a same vertical layer with the high-index strips 661 and 662 being positioned on opposite lateral sides of the low-index strip 660, as shown in FIG. 11. Note that FIG. 11 is not intended to depict the thicknesses and widths of the strips 660, 661 and 662, and these strips may have any suitable thickness and widths that produce a desired optical mode. In some examples, the widths of the strips 660, 661, and 662 may be similar to the thicknesses described above with respect to the layers 60, 61, and 62 (and implementation examples thereof), and the thicknesses of the strips 660, 661, and 662 may be similar to the widths described above with respect to the strips 60, 61, and 62 (and implementation examples thereof), such that core 640 has a similar structure as one of the cores described above except rotated ninety degrees. For example, in some instances the high index strips 661 and 662 may be about 0.1 μm wide (along y-axis) and may be about 1.0 μm thick (along z-axis).

The core 640 is at least partially surrounded, in cross-section, by the cladding 630. FIG. 11 shows the cladding 630 fully surrounding the core 640, but the cladding may have other configurations, including any of the other configurations described herein with respect to the cladding of the other optical devices.

FIG. 12 illustrates an example optical device 710, which is an example of the optical device 10. The optical device 710 includes a substrate 715 and a WOA 720 formed thereon. The WOA 720 includes cladding 730 formed on the substrate 715 and a core 740 formed on/in the cladding. The core 740 includes a high-index layer 762, a high-index layer 761, and a low-index layer 760 sandwiched between the layers 762 and 761. Materials and configurations for the various components of the optical device 710 may be as described above in relation to the optical device 10 and 110, unless otherwise specified.

A notable characteristic of the WOA 720 is that it includes additional high-index strips/layers 763 and 764, in addition to the other high-index strips/layers 761 and 762. These additional high-index layers 763 and 764 are positioned in the same vertical layer as the low-index layer 760, with the high-index layers 763 and 764 being positioned on opposite lateral sides of the low-index layer 760, as shown in FIG. 12. As a result of this configuration, the low-index layer 760 is surrounded, in a cross-section, on all sides thereof by higher index layers. In other words, the low-index layer 760 is sandwiched in a vertical direction between the high-index layers 761 and 762, and is also sandwiched in a horizontal direction between high-index layers 763 and 764. In some examples, high-index layers 763 and 764 may be formed from the same material as one another. In some examples, high-index layers 761, 762, 763, and 764 are all formed from the same material, in which case the high-index layers 761, 762, 763, and 764 may appear as a single monolithic layer into which the low-index layer 760 has been embedded. In other examples, one or more of the high-index layers 761, 762, 763, and 764 may be formed from a different material than one or more others of the high-index layers 761, 762, 763, and 764.

Note that FIG. 12 is not intended to depict the thicknesses and widths of the layers 760, 761, 762, 763, and 764, and these layers may have any suitable thickness and widths that produce a desired optical mode.

The core 740 is at least partially surrounded, in cross-section, by the cladding 730. FIG. 11 shows the cladding 730 fully surrounding the core 740, but the cladding may have other configurations, including any of the other configurations described herein with respect to the cladding of the other optical devices.

Herein, the term “strip” is used in relation to the high and low-index strips which form the layered cores disclosed herein. This term is used broadly to refer to a particular body of material, and is not intended to imply anything about the shape, size, or other characteristics of that body. For example, a strip may fill an entire layer within an optical device (i.e., the strip can extend fully across a width of the device) or it may comprise just a portion of a layer (i.e., the strip may extend less than all the way across the width of the device, and other material bodies may be formed within the same layer in which the strip is formed). Strips that are vertically stacked relative to one another may also be referred to as “layers.” In such cases, it should be understood that reference to a strip as a “layer” does not imply that the strip necessarily extends across or occupies an entire vertical layer within the optical device, but rather it merely implies that the strips (layers) of the core are vertically stacked on one another.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An optical device, comprising:
a substrate; and
a waveguide optical amplifier formed on the substrate and comprising:
a core defining an optical path through the waveguide optical amplifier; and
cladding abutting at least one side of the core,
wherein the core comprises:
a first high-index strip comprising a first material with a first refractive index;
a second high-index strip comprising a second material with a second refractive index; and
a low-index strip disposed between and abutting the first and second high-index strips and comprising a third material with a third refractive index, which is doped with a dopant to amplify signal light traveling through the optical path, and
wherein the third refractive index is lower than the first and second refractive indices.

2. The optical device of claim 1,
wherein the first and second materials are the same as one another.

3. The optical device of claim 2,
wherein the first, second, and third materials are silicon-based.

4. The optical device of claim 3, wherein one of:
the first and second materials are silicon (Si) and the third material is silicon nitride (Si₍ₓ₎N_{(y)}); and
the first and second materials are silicon nitride and the third material is Silicon oxynitride (Si₍ₓ₎O_{(y)}N_{(z)}).

5. The optical device of claim 1,
wherein the first and second materials are different from one another.

6. The optical device of claim 1,
wherein the first high-index strip is formed in a first layer disposed on a portion of the cladding;
wherein the low-index strip is formed in a second layer disposed on the first layer;
wherein the second high-index strip is formed in a third layer disposed on the second layer.

7. The optical device of claim 6,
wherein the first high-index strip extends laterally beyond lateral edges of the low-index strip.

8. The optical device of claim 7,
wherein the first high-index strip comprises one or more trenches arranged laterally beyond the lateral edges of the low-index strip.

9. The optical device of claim 7,
wherein the second high-index strip extends laterally beyond lateral edges of the low-index strip.

10. The optical device of claim 9,
wherein the second high-index strip comprises one or more trenches arranged laterally beyond the lateral edges of the low-index strip.

11. The optical device of claim 9,
wherein the core further comprises third and fourth high-index strips disposed in the second layer on opposite lateral sides of the low-index strip.

12. The optical device of claim 11,
wherein the first, second, third, and fourth high-index strips are formed from a same material as one another and are joined together to form a body surrounding the low-index strip in cross-section.

13. The optical device of claim 1,
wherein the first high-index strip, the second high-index strip, and the low-index strip are formed in a same layer disposed on a portion of the cladding, with the first high-index strip and the second-high-index strip disposed on opposite lateral sides of the low-index strip.

14. The optical device of claim 1,
wherein the core has an optical confinement in the low-index strip that is greater than an optical confinement of an alternative core comprising the same material and same dimensions as the low-index strip but without the first and second high-index strips.

15. The optical device of claim 14,
wherein the optical confinement in the low-index strip is at least twice the optical confinement of the alternative core.

16. The optical device of claim 15,
wherein the optical confinement in the low-index strip is at least three times the optical confinement of the alternative core.

17. The optical device of claim 1,
wherein a mode profile in the low-index strip is flatter than a mode profile in the alternative core.

18. The optical device of claim 1, further comprising:
at least one additional optical component, separate from the waveguide optical amplifier, formed on the substrate and optical coupled to the waveguide optical amplifier to form a photonic integrated circuit.

19. A method of forming a waveguide optical amplifier, comprising:
forming, on a substrate, waveguide cladding including at least a lower cladding layer;
forming a waveguide core defining an optical path by:
forming a first high-index strip on the lower cladding layer, the first high-index strip comprising a first material with a first refractive index;
forming a low-index strip on the first high-index strip, the low-index strip comprising a third material with a third refractive index which is doped with a dopant to amplify signal light traveling along the optical path; and
forming a second high-index strip on the low-index strip, the second high-index strip comprising a second material with a second refractive index;
wherein the third refractive index is lower than the first and second refractive indices.

20. A method of forming a waveguide optical amplifier, comprising:
forming, on a substrate, waveguide cladding including at least a lower cladding layer;
forming a waveguide core defining an optical path by:
forming a first high-index strip on the lower cladding layer, the first high-index strip comprising a first material with a first refractive index;
forming a second high-index strip on the lower cladding layer, the second high-index strip comprising a second material with a second refractive index; and
forming a low-index strip on the lower cladding layer, the low-index strip comprising a third material with a third refractive index which is doped with a dopant to amplify signal light traveling along the optical path,
wherein the first and second high-index strips and the low-index strip are formed in a same vertical layer as one another with the first and second high-index strips disposed on opposite lateral sides of the low-index strip; and
wherein the third refractive index is lower than the first and second refractive indices.
